(19) United States
(12) Patent Application Publication
(10) Pub. No.: US 2026/0181843 A1
(43) Pub. Date: Jun. 25, 2026

(54) ELECTRIC COMPRESSOR

(71) Applicant: KABUSHIKI KAISHA TOYOTA JIDOSHOKKI, Aichi (JP)

(72) Inventors: Yoshifumi TADA, Aichi (JP); Katsuya USAMI, Aichi (JP); Kenta MATSUOKA, Aichi (JP)

(73) Assignee: KABUSHIKI KAISHA TOYOTA JIDOSHOKKI, Aichi (JP)

(21) Appl. No.: 19/421,628

(22) Filed: Dec. 16, 2025

(30) Foreign Application Priority Data
Dec. 25, 2024 (JP) 2024-228938

(51) Int. Cl. H05K 7/20; F04B 35/04; F04B 53/08; F04C 29/00; F04C 29/04; H05K 7/14

(52) U.S. Cl. CPC H05K 7/209; F04B 35/04; F04B 53/08; F04C 29/0085; F04C 29/047; H05K 7/1432

(57) ABSTRACT

An electric compressor includes an inverter housing accommodating an inverter. The inverter has a circuit board, a power element, and a metal base circuit board. The power element has a plurality of leads that is electrically connected to a switching element in a mold member, extends through a side surface of the mold member, and is electrically connected to a circuit pattern. The plurality of leads each has a first portion and a second portion. The metal base circuit board is disposed between the power element and the inverter housing and includes a metal layer and an insulation layer integrally formed with the metal layer. The insulation layer has a mold member facing portion and a lead facing portion.

### CROSS-REFERENCE OF THE RELATED APPLICATION

This application claims priority to Japanese Patent Application No. 2024-228938 filed on Dec. 25, 2024, the entire disclosure of which is incorporated herein by reference.

### BACKGROUND ART

The present disclosure relates to an electric compressor.

Japanese Patent Application Publication No. 2008-128142 discloses an inverter-integrated electric compressor in which an inverter device and an electric compressor are integrated. The inverter device is assembled into an inverter accommodation member, which is an inverter housing provided in a housing of the electric compressor. The inverter device includes an insulated gate bipolar transistor (IGBT) as a power element, a power board as a circuit board, and a metal plate serving as a heat sink that is fixed to the inverter accommodation member. The IGBT includes a mold member molded with resin and a terminal, which is a lead that extends from a side surface of the mold member. The mold member is placed on the metal plate and connected to the power board by the terminal. The metal plate releases the heat generated in the IGBT toward the inverter accommodation member. The IGBT is fixed to the metal plate through an insulation sheet.

With the increasing adoption of electric vehicles, the power supply voltage of an electric compressor mounted on the electric vehicles becomes higher such as 800 V. Thus, it is necessary to secure both an insulation distance and a creepage distance between a lead and a metal plate.

In the configuration of the above-described Publication, the insulation distance between the lead and the metal plate may be secured by an amount of thickness of the insulation sheet. However, in the configuration, there is a risk that the creepage distance between the lead and the metal plate may not be sufficiently secured. When the thickness of the insulation sheet is increased to secure the creepage distance between the lead and the metal plate, the electric compressor increases in size, and a heat releasing performance of the power element decreases. Thus, it is desired to secure the creepage distance sufficiently, to suppress an increase in size in the thickness direction of the electric compressor, and to suppress a decrease in the heat releasing performance of the power element.

### SUMMARY

According to one aspect of the present disclosure, there is provided an electric compressor including, a compression part configured to compress fluid, an electric motor configured to drive the compression part, an inverter configured to drive the electric motor; and an inverter housing accommodating the inverter. The inverter has a circuit board on which a circuit pattern is provided, the circuit pattern forming a circuit of the inverter, and a power element including a mold member in which a switching element forming the circuit of the inverter is molded in resin, and a plurality of leads that is electrically connected to the switching element in the mold member, extends through a side surface of the mold member, and is electrically connected to the circuit pattern. The plurality of leads each has a first portion that extends toward an outside of the mold member from the side surface of the mold member, and a second portion that is bent from the first portion and extends toward the circuit board. The inverter further includes a metal base circuit board disposed between the power element and the inverter housing. The metal base circuit board includes a metal layer that releases heat generated in the power element to the inverter housing, and an insulation layer that is integrally formed with the metal layer on a surface of the metal layer. The power element and the metal base circuit board are accommodated in the inverter housing so that the first portion, the insulation layer, and the metal layer are arranged in this order in a thickness direction of the metal base circuit board. The insulation layer has a mold member facing portion extending in the thickness direction of the metal base circuit board so that the mold member facing portion faces the mold member and a lead facing portion that extends from the mold member facing portion so that the lead facing portion faces at least the first portion in the thickness direction of the metal base circuit board.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a schematic view illustrating an electric compressor and a vehicle air conditioner;

FIG. 2 is an exploded perspective view illustrating a circuit board, a power element, and a metal base circuit board;

FIG. 3 is a perspective view illustrating the power element, and the metal base circuit board;

FIG. 4 is a cross-sectional view illustrating the power element, and the metal base circuit board; and

FIG. 5 is a top view illustrating the circuit board, the power element, and the metal base circuit board.

### DETAILED DESCRIPTION OF THE EMBODIMENTS

The following will describe an embodiment of an electric compressor. The electric compressor of the present embodiment is used in a vehicle air conditioner mounted on a vehicle.

### Vehicle Air Conditioner

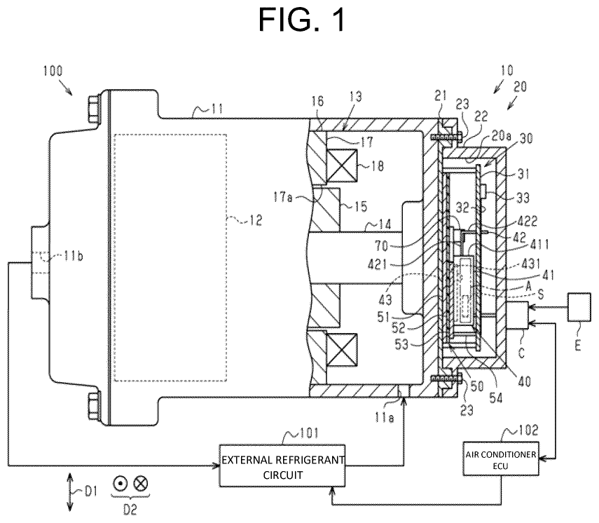

As illustrated in FIG. 1, a vehicle air conditioner 100 has an electric compressor 10 and an external refrigerant circuit 101 through which refrigerant as fluid is supplied to the electric compressor 10. The vehicle air conditioner 100 is mounted on a vehicle (not illustrated). The external refrigerant circuit 101 includes a heat exchanger and an expansion valve, for example. The vehicle air conditioner 100 provides heating and cooling to a vehicle cabin by the compression of the refrigerant by the electric compressor 10 and the heat exchange and the expansion of the refrigerant through the external refrigerant circuit 101.

The vehicle air conditioner 100 has an air conditioner ECU 102 that entirely controls the vehicle air conditioner 100. The air conditioner ECU 102 is configured to receive parameters such as a temperature in the vehicle or a set temperature and send commands such as a command of turning the electric compressor 10 on or off, based on these parameters.

### Outline of Electric Compressor

The electric compressor 10 includes a housing 11, a compression part 12, an electric motor 13, an inverter housing 20, and an inverter 30. The electric compressor 10 is electrically connected to a power source E mounted on the vehicle and driven by the power source E. In the present embodiment, a voltage of the power source E is 800 V.

The housing 11 has a generally cylindrical shape as a whole. The housing 11 is made of a material with thermal conductivity. An example of the material of the housing 11 is aluminum. A suction port 11a and a discharge port 11b are formed in the housing 11. Refrigerant is drawn into the housing 11 from the external refrigerant circuit 101 through the suction port 11a. The refrigerant drawn into the housing 11 is discharged to an outside of the housing 11 through the discharge port 11b. The discharge port 11b is formed on one end portion of the housing 11 in an axial direction thereof. In addition, the suction port 11a is located close to the other end portion of the housing 11 opposite from the end portion on which the discharge port 11b is formed.

The compression part 12 is accommodated in the housing 11. The compression part 12 compresses fluid. In the present embodiment, the compression part 12 compresses the refrigerant drawn into the housing 11 through the suction port 11a. The compression part 12 discharges the compressed refrigerant through the discharge port 11b. The compression part 12 is not limited to a specific configuration. Examples of the specific configuration of the compression part 12 include a scroll type, a piston type, and a vane type.

The electric motor 13 includes a rotary shaft 14, a rotor 15, and a stator 16. The electric motor 13 is accommodated in the housing 11. The electric motor 13 drives the compression part 12. The rotary shaft 14 has a columnar shape and is rotatably supported relative to the housing 11. An axial direction of the rotary shaft 14 coincides with the axial direction of the housing 11. The rotor 15 has a columnar shape and fixed to the housing 11. A permanent magnet (not illustrated) is embedded in the rotor 15.

The stator 16 includes a stator core 17 and a coil 18. The stator 16 is fixed to the housing 11. The stator core 17 faces the rotor 15 in a radial direction of the rotary shaft 14. The stator core 17 has a cylindrical shape and fixed to the housing 11. An axial direction of the stator core 17 coincides with the axial direction of the rotary shaft 14. Teeth 17a are formed on an inner peripheral surface of the stator core 17. The coil 18 is wound around the teeth 17a. In the present embodiment, the electric motor 13 is a three-phase motor. That is, the coil 18 is a three-phase structure that is formed of a U-phase coil, a V-phase coil, and a W-phase coil.

The inverter housing 20 includes an inverter plate 21 and an inverter cover 22. The inverter housing 20 is attached to the housing 11. Specifically, the inverter housing 20 is attached to the end portion of the housing 11 in the axial direction of the housing 11, which is opposite from the end portion on which the discharge port 11b is formed.

The inverter plate 21 has a plate shape and a thickness direction of the inverter plate 21 coincides with the axial direction of the housing 11. The inverter cover 22 is attached to the housing 11 through the inverter plate 21. More specifically, the inverter cover 22 is attached to the end portion of the housing 11 in the axial direction of the housing 11 with the inverter plate 21 interposed between the inverter cover 22 and the housing 11. The inverter plate 21 and the inverter cover 22 are fixed to the housing 11 with a bolt 23.

The inverter housing 20 has a storage space 20a. The storage space 20a is defined by the inverter plate 21 and the inverter cover 22.

### Inverter

The inverter 30 includes a circuit board 31, a controller 33, a plurality of power elements 40, a metal base circuit board 50, and a temperature sensor 70. The inverter 30 is accommodated in the inverter housing 20. The inverter 30 is located in the storage space 20a. That is, the circuit board 31, the power elements 40, and the metal base circuit board 50 are accommodated in the inverter housing 20. The inverter 30 is fixed to the housing 11 through the inverter housing 20.

The inverter 30 is cooled by the refrigerant drawn into the housing 11 through the suction port 11a. More specifically, the heat generated in the inverter 30 is transmitted to the housing 11 through the inverter housing 20. The heat transmitted to the housing 11 is transmitted to the refrigerant inside the housing 11. That is, the inverter 30 transmits the heat generated in the inverter 30 to the refrigerant through the inverter housing 20 and the housing 11.

The inverter 30 drives the electric motor 13. The inverter 30 is configured to output power to the electric motor 13 after converting direct current input from the power source E into alternating current. More specifically, the inverter 30 is electrically connected to the power source E through an external connector C provided on the inverter cover 22. In addition, the inverter 30 is electrically connected to the coil 18 provided in the electric motor 13 by a connector and a wire that are not illustrated and outputs alternating current to the coil 18. The inverter 30 is connected to the air conditioner ECU 102 through the external connector C.

The circuit board 31 has a thin plate shape. A thickness direction of the circuit board 31 coincides with the axial direction of the housing 11. The power elements 40 and various electronic components (not illustrated) are mounted on the circuit board 31.

A circuit pattern 32 is formed on the circuit board 31 to configure the circuit of the inverter 30. The circuit pattern 32 is formed on a surface of the circuit board 31 facing the inverter cover 22 in the thickness direction of the circuit board 31. The circuit pattern 32 is electrically connected to the external connector C. In addition, the power elements 40 and the various electronic components that are mounted on the circuit board 31 are electrically connected to each other through the circuit pattern 32. The power source E supplies electric power to the circuit pattern 32 through the external connector C. The electric power supplied through the external connector C is supplied to the power elements 40 and the various electronic components through the circuit pattern 32.

The controller 33 is mounted on the circuit board 31. The controller 33 is electrically connected to the circuit pattern 32. The controller 33 is electrically connected to both the power elements 40 and the various electronic components through the circuit pattern 32. The controller 33 is configured to control the power elements 40. The controller 33 controls the inverter 30 by controlling the operation of the power elements 40.

The controller 33 is implemented by a hardware processor such as a central processing unit (CPU) that executes programs (software). Also, a part or all of these components may be operated by a hardware (a circuit portion including circuitry) such as large scale integration (LSI), an application specific integrated circuit (ASIC), a field-programmable gate array (FPGA), or a graphics processing unit (GPU), or may be operated by the cooperation of software and hardware. The program may be stored in a storage device, which is provided in the electric compressor 10 and includes a non-volatile storage medium such as a flash memory.

### Power Elements

The power elements 40 are disposed in the storage space 20a. The power elements 40 are disposed between the circuit board 31 and the inverter plate 21 in the storage space 20a. The power elements 40 of the present embodiment each are a discrete-type IGBT. The power elements 40 each are controlled by the controller 33 to turn on and off. In addition, the power elements 40 of the present embodiment each include a freewheeling diode. However, the power elements 40 do not have to include the freewheeling diode. In this case, the inverter 30 includes freewheeling diodes corresponding to the power elements 40.

The inverter 30 has a plurality of the power elements 40. The inverter 30 converts the supplied power by controlling the power elements 40 to turn on and off. Note that only one of the power elements 40 provided in the inverter 30 is illustrated in FIG. 1 to FIG. 5. The number of the power elements 40 may be changed as appropriate depending on the configuration of the electric motor 13 driven by the inverter 30. The electric motor 13 of the present embodiment, which is the three-phase motor, includes six power elements 40.

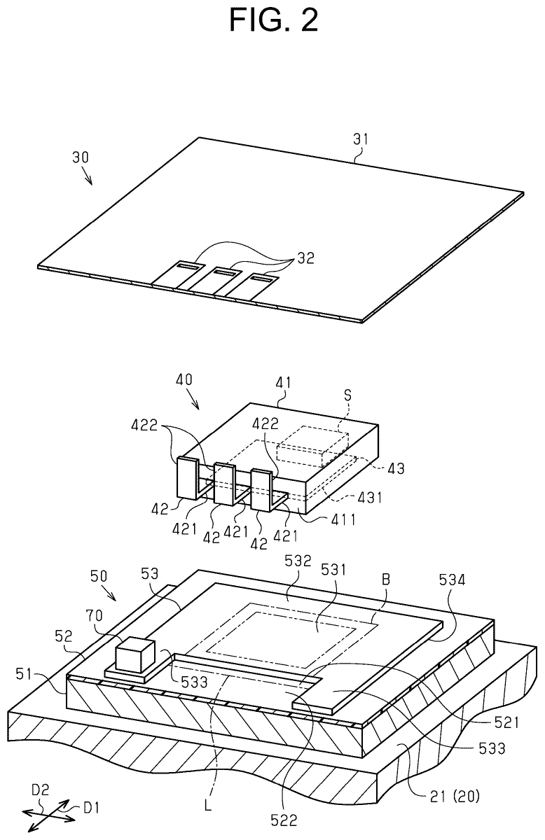

As illustrated in FIG. 1 and FIG. 2, the power elements 40 each have a mold member 41 and a plurality of leads 42. In the present embodiment, the power elements 40 each include three leads 42 as illustrated in FIG. 2. The number of the leads 42 is not limited to three, but may be changed as appropriate depending on the specific configuration of the power elements 40. In the present embodiment, the three leads 42 serve as a gate terminal, a collector terminal, and an emitter terminal, respectively. One of the leads 42 serving as the gate terminal is connected to the controller 33 illustrated in FIG. 1 through the circuit pattern 32. The power elements 40 each switch one of the leads 42, which serves as the gate terminal, on and off based on a signal input from the controller 33.

As illustrated in FIG. 2, the mold member 41 has a block shape. As illustrated in FIG. 1, the mold member 41 is formed by molding a switching element S, which constitutes a circuit of the inverter 30, with resin A. Specifically, the switching element S is accommodated inside the mold member 41, and the mold member 41 is formed by filling the resin A into a space in which the switching element S is accommodated. The power elements 40 are turned on and off by switching operation of the switching element S. The heat generated in the switching element S by the switching operation is transmitted to an outside of the mold member 41 through the resin A.

The power elements 40 are accommodated in the inverter housing 20 so that the thickness direction of the mold member 41 coincides with the thickness direction of both the circuit board 31 and the inverter plate 21. That is, one of two surfaces of the mold member 41 in the thickness direction faces the inverter plate 21, and the other of the two surfaces faces the circuit board 31.

As illustrated in FIG. 1, and FIG. 2, the mold member 41 includes a heat releasing plate 43. The heat releasing plate 43 has a plate shape and is made of a metal material. The heat releasing plate 43 is formed integrally with the mold member 41. The heat releasing plate 43 is integrated in the mold member 41. The heat releasing plate 43 includes a heat releasing surface 431 exposed to the outside of the mold member 41, which is not illustrated in detail. The heat releasing surface 431 is exposed to one of the surfaces of the mold member 41 in the thickness direction of the mold member 41. The heat releasing surface 431 is flush with the one of the surfaces of the mold member 41.

In the mold member 41, the heat releasing plate 43 is exposed on a surface opposite from a surface facing the circuit board 31. That is, the heat releasing surface 431 faces the inverter plate 21 in the thickness direction of the mold member 41.

The heat releasing plate 43 releases heat of the switching element S. Specifically, in a case where the switching element S generates heat inside the mold member 41, the heat is transmitted to the heat releasing plate 43 through the resin A filled in the mold member 41. The heat releasing plate 43 releases such heat to the outside of the power elements 40 through the heat releasing surface 431.

The leads 42 are provided in the mold member 41. The leads 42 are made of an electrically conductive material. The leads 42 extend through a side surface of the mold member 41. The leads 42 are electrically connected to the switching element S in the mold member 41 and extend from an inside to an outside of the mold member 41 through a terminal-side surface 411 that is one of side surfaces of the mold member 41.

Each of the three leads 42 extends through the terminal-side surface 411. The terminal-side surface 411 is one of the side surfaces of the mold member 41. In detail, in the mold member 41, the terminal-side surface 411 is one of the surfaces of the mold member 41 that extends parallel with the thickness direction of the mold member 41.

In the following, a direction perpendicular to the terminal-side surface 411 is defined as a first direction D1. In addition, a direction perpendicular to both the thickness direction of the mold member 41 and the first direction D1 is referred to as a second direction D2. The three leads 42 are arranged in one direction in the terminal-side surface 411. The three leads 42 illustrated in FIG. 2 are arranged in the terminal-side surface 411 along the second direction D2.

The three leads 42 are electrically connected to the circuit pattern 32. An extended portion of each of the leads 42, which extends through the mold member 41, is electrically connected to the circuit board 31. The leads 42 electrically connect the switching element S inside the power elements 40 to the circuit board 31. In the following description, an end of the portion of each of the leads 42 extending from the mold member 41 adjacent to the terminal-side surface 411 is referred to as a base end portion, and an end of the portion of each of the leads 42 extending from the mold member 41 adjacent to the circuit board 31 is referred to as a distal end portion.

The three leads 42 each include a first portion 421 and a second portion 422 in the portion extending from the inside to the outside of the mold member 41. The first portion 421 is a portion that is located close to the base end portion of each of the leads 42. The first portion 421 extends toward the outside of the mold member 41 from the side surface thereof. The first portion 421 corresponds to a portion of each of the leads 42 that stands from the terminal-side surface 411. The first portion 421 extends in the first direction D1.

The second portion 422 is a portion that is located close to the distal end portion of each of the leads 42. The second portion 422 is bent from the first portion 421 and extends toward the circuit board 31. The second portion 422 corresponds to a portion of each of the leads 42 that is located close to the circuit board 31.

Each of the leads 42 extends through the circuit board 31 through the second portion 422, and the distal end portion protrudes from a surface of the circuit board 31 opposite from a surface thereof facing the mold member 41. With this configuration, each of the leads 42 is connected to the circuit pattern 32 in a portion that is located close to the distal end portion protruding from the circuit board 31.

### Metal Base Circuit Board

As illustrated in FIG. 1, the metal base circuit board 50 has a metal layer 51, an insulation layer 52, and an element-side metal layer 53. The metal base circuit board 50 has a sheet shape. The metal base circuit board 50 is accommodated in the storage space 20a. The metal base circuit board 50 is disposed between the power elements 40 and the inverter housing 20. More specifically, the metal base circuit board 50 is provided between the power elements 40 and the inverter plate 21. The metal base circuit board 50 is provided on the inverter plate 21 so that the thickness direction of the metal base circuit board 50 coincides with the thickness direction of the inverter plate 21. That is, the thickness direction of the metal base circuit board 50 coincides with the thickness direction of each of the inverter plate 21, the mold member 41, and the circuit board 31. One of the surfaces of the metal base circuit board 50 in the thickness direction thereof faces the inverter plate 21 and the other of the surfaces faces the power elements 40.

In the metal base circuit board 50, the metal layer 51, the insulation layer 52, and the element-side metal layer 53 are layered in this order. The metal layer 51, the insulation layer 52, and the element-side metal layer 53 are integrated to form the metal base circuit board 50. In the metal base circuit board 50 of the present embodiment, a thickness of the metal layer 51 is 1.0 mm, a thickness of the insulation layer 52 is 0.15 mm, and a thickness of the element-side metal layer 53 is 0.035 mm. Note that the thickness of the metal base circuit board 50, as illustrated in FIG. 1 to FIG. 5, is illustrated in an exaggerated manner so as to show easily the structure in the thickness direction of the metal base circuit board 50.

### Metal Layer

As illustrated in FIG. 1 and FIG. 2, the metal layer 51 forms a portion of the metal base circuit board 50 close to one of the surfaces of the metal base circuit board 50 in the thickness direction thereof. More specifically, the metal layer 51 forms a portion of the metal base circuit board 50 close to the inverter plate 21 in the thickness direction thereof. In the metal base circuit board 50, the metal layer 51 faces the inverter plate 21.

The metal layer 51 is made of a metal material with thermal conductivity. The material of the metal layer 51 of the present embodiment is aluminum. In the metal base circuit board 50, the metal layer 51 is in contact with the inverter plate 21. With this configuration, the metal base circuit board 50 is connected to the inverter plate 21 in the metal layer 51 in a thermally conductive manner.

### Insulation Layer

The insulation layer 52 is integrally formed over a surface of the metal layer 51. The insulation layer 52 is formed on the surface of the metal layer 51, which is opposite from a surface of the metal layer 51 in contact with the inverter plate 21 in the thickness direction of the metal base circuit board 50. The insulation layer 52 is interposed between the metal layer 51 and the power elements 40 in the thickness direction of the metal base circuit board 50. More specifically, the insulation layer 52 is interposed between the metal layer 51 and the mold member 41 in the thickness direction of the metal base circuit board 50. The insulation layer 52 is interposed between the heat releasing plate 43 and the metal layer 51.

The insulation layer 52 is interposed between the metal layer 51 and the first portion 421 of each of the leads 42 in the thickness direction of the metal base circuit board 50. That is, the power elements 40 and the metal base circuit board 50 are accommodated in the inverter housing 20 so that the first portion 421, the insulation layer 52, and the metal layer 51 are arranged in this order in the thickness direction of the metal base circuit board 50.

The insulation layer 52 includes a mold member facing portion 521 and a lead facing portion 522. The insulation layer 52 is made of a material with insulation property. The insulation layer 52 of the present embodiment is made of a resin material. The insulation layer 52 provides insulation between the power elements 40 and the metal layer 51.

The mold member facing portion 521 is a portion of the insulation layer 52. The mold member facing portion 521 extends in the thickness direction of the metal base circuit board 50 so that the mold member facing portion 521 faces the mold member 41. The mold member facing portion 521 is interposed between the heat releasing plate 43 and the metal layer 51. The mold member facing portion 521 of the present embodiment forms a portion of the insulation layer 52 that overlaps with the mold portion 41 in the thickness direction of the of the metal base circuit board 50. The lead facing portion 522 is a portion of the insulation layer 52. The lead facing portion 522 extends from the mold member facing portion 521 so that the lead facing portion 522 faces at least the first portion 421 in the thickness direction of the metal base circuit board 50.

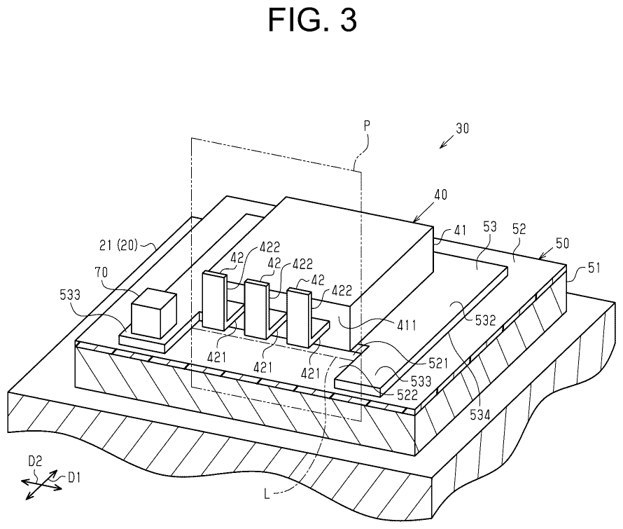

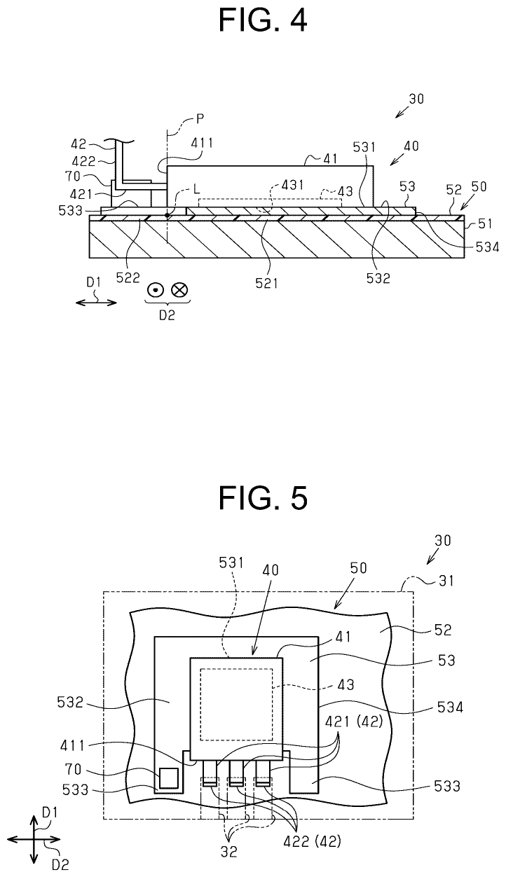

The following will describe an area in which the insulation layer 52 is provided in the metal layer 51 with reference to FIG. 3 and FIG. 4. The following will describe an imaginary flat surface P, which is partially formed of a terminal-side surface 411. The imaginary flat surface P only needs to be partially formed of the terminal-side surface 411. An area of the imaginary flat surface P only needs to be nearly the size of an intersection of the imaginary flat surface P and the metal base circuit board 50. That is, the area of the imaginary flat surface P is not limited to the illustration in FIG. 3 and FIG. 4.

The imaginary flat surface P intersects with the metal base circuit board 50. In other words, the imaginary flat surface P intersects with the metal layer 51 and the insulation layer 52. As illustrated in FIG. 3 and FIG. 4, a portion where the imaginary flat surface P intersects with the insulation layer 52 is shown by an imaginary line L. That is, the imaginary line L is a straight line that is located on the imaginary flat surface P and on the insulation layer 52. The imaginary line L extends in the second direction D2.

The imaginary flat surface P extends in parallel with each of the thickness direction of the mold member 41 and the thickness direction of the metal base circuit board 50. Thus, the imaginary flat surface P coincides with the imaginary line L when the metal base circuit board 50 is viewed from the thickness direction thereof in a plan view. In other words, the terminal-side surface 411 coincides with the imaginary line L when the metal base circuit board 50 is viewed from the thickness direction thereof in the plan view.

In the insulation layer 52, the imaginary line L corresponds to a border between the mold member facing portion 521 and the lead facing portion 522. Specifically, in the first direction D1, the insulation layer 52 has the mold member facing portion 521 closer to the mold member 41 than to the imaginary line L and the lead facing portion 522 closer to the leads 42 than to the imaginary line L. The mold member facing portion 521 extends from the imaginary line L, and corresponds to a portion of the insulation layer 52 extending along the mold member 41 in the thickness direction of the metal base circuit board 50. That is, only a portion of the mold member facing portion 521 located close to the imaginary line L is illustrated in FIG. 3.

The insulation layer 52 extends from the imaginary line L where the imaginary flat surface P including the terminal-side surface 411 intersects with the metal base circuit board 50 so that the insulation layer 52 faces at least the first portion 421 in the thickness direction of the metal base circuit board 50. In other words, the metal base circuit board 50 includes the lead facing portion 522 in the insulation layer 52 so as to overlap with at least the first portion 421 when the metal base circuit board 50 is viewed from the thickness direction thereof in the plan view. In other words, the insulation layer 52 includes the lead facing portion 522 that extends from the imaginary line L so as to provide insulation between at least the first portion 421 and the metal layer 51. In addition, the metal base circuit board 50 includes the mold member facing portion 521 in the insulation layer 52 so as to overlap with at least the mold member 41 when the metal base circuit board 50 is viewed from the thickness direction thereof in the plan view. The insulation layer 52 includes the mold member facing portion 521 so as to provide insulation between at least a portion of the mold member 41 located close to the leads 42 and the metal layer 51.

As described above, the insulation layer 52 is formed on the metal layer 51 so as to provide insulation between at least the first portion 421 and the metal layer 51. The insulation layer 52 may be formed over an entire surface of the metal layer 51 opposite from the surface of the metal layer 51 in contact with the inverter plate 21. Alternatively, the insulation layer 52 may be partially formed on the surface of the metal layer 51 opposite from the surface in contact with the inverter plate 21. When the insulation layer 52 is partially formed on the surface of the metal layer 51 opposite from the surface in contact with the inverter plate 21, a plurality of the insulation layers 52 is formed so as to provide insulation between the first portion 421 of each of the plurality of the power elements 40 and the metal layer 51.

In short, the insulation layer 52 may be formed at any position on the surface of the metal layer 51 opposite from the surface of the metal layer 51 in contact with the inverter plate 21, as long as the insulation layer 52 provides insulation between the first portion 421 and the metal layer 51. The insulation layer 52 of the present embodiment is formed over the entire surface of the metal layer 51 opposite from the surface of the metal layer 51 in contact with the inverter plate 21. Note that, in the metal layer 51, when the plurality of the insulation layer 52 is provided, each of the insulation layers 52 includes the mold member facing portion 521 and the lead facing portion 522.

When the insulation layer 52 is partially formed on the surface of the metal layer 51 opposite from the surface in contact with the inverter plate 21, the metal base circuit board 50 includes the insulation layer 52 so as to provide insulation between the first portion 421 and the metal layer 51. Specifically, the metal base circuit board 50 includes the insulation layer 52 so that a spaced distance between the first portion 421 and a portion of the metal layer 51 that is not covered by the insulation layer 52 becomes greater than or equal to a desired distance. That is, an area and a position of the insulation layer 52 in the metal base circuit board 50 are set so that the spaced distance from each of portions of the first portion 421 as a starting point to the portion of the metal layer 51 that is not covered by the insulation layer 52 becomes greater than or equal to the desired distance. Here, each of the portions of the first portion 421 refers to a segment obtained by dividing the first portion 421 into a plurality of parts at any desired width in a direction in which the first portion 421 extends.

The desired distance described above, in the spaced distance between the first portion 421 and the portion of the metal layer 51 that is not covered by the insulation layer 52, may be changed as appropriate depending on the voltage of the power source E, that is, the voltage applied to the power elements 40. In the present embodiment, the insulation layer 52 is provided so that the spaced distance between the first portion 421 and the portion of the metal layer 51 that is not covered by the insulation layer 52 is greater than or equal to 5 mm.

### Element-Side Metal Layer

As illustrated in FIG. 1 and FIG. 2, the metal base circuit board 50 has the element-side metal layer 53 on the side opposite from the metal layer 51 with the insulation layer 52 interposed between the element-side metal layer 53 and the metal layer 51. The power elements 40 and the metal base circuit board 50 are accommodated in the inverter housing 20 so that the mold member 41, the element-side metal layer 53, the insulation layer 52, and the metal layer 51 are arranged in this order in the thickness direction of the metal base circuit board 50. In short, the metal base circuit board 50 includes the insulation layer 52 interposed between the metal layer 51 and the element-side metal layer 53. In other words, the element-side metal layer 53 is provided on the metal layer 51 via the insulation layer 52.

The element-side metal layer 53 is provided on a surface of the insulation layer 52 opposite from a surface of the insulation layer 52 facing the metal layer 51. The element-side metal layer 53 forms a portion of the metal base circuit board 50 that is located close to the surface facing the power elements 40. That is, the metal base circuit board 50 faces the power elements 40 via the element-side metal layer 53.

As illustrated in FIG. 2, the element-side metal layer 53 includes a main portion 531, an outer portion 532 that extends from the main portion 531, and two protruding portions 533 that further extend from the outer portion 532. The element-side metal layer 53 is made of a metal material with thermal conductivity. The element-side metal layer 53 of the present embodiment is made of copper. The element-side metal layer 53 is formed by metal forming. That is, the main portion 531, the outer portion 532, and the protruding portions 533 are portions of the element-side metal layer 53, which are made of the same metal material.

The element-side metal layer 53 includes an edge portion 534. The edge portion 534 coincides with a border between the element-side metal layer 53 and the insulation layer 52 when the metal base circuit board 50 is viewed from the thickness direction thereof in the plan view. In short, the element-side metal layer 53 is a portion surrounded by the closed edge portion 534.

As illustrated in FIG. 1, a conductive member 54 is provided on the element-side metal layer 53. The conductive member 54 electrically connects the element-side metal layer 53 to the circuit board 31. An example of the conductive member 54 is a busbar. The conductive member 54 may be a wire.

As illustrated in FIG. 2, the element-side metal layer 53 includes the main portion 531 located in a portion facing the mold member 41 of each of the power elements 40. As illustrated in FIG. 2, a boundary B, which separates the main portion 531 of the element-side metal layer 53 from portions different from the main portion 531 is indicated by a chain line. The boundary B has a rectangular shape. The boundary B has two sides extending in the first direction D1 and two sides extending in the second direction D2. One of the four sides of the boundary B coincides with a portion of the edge portion 534, as viewed in the thickness direction of the element-side metal layer 53. In other words, as viewed in the thickness direction of the element-side metal layer 53, the boundary B coincides with the portion of the edge portion 534 in one of the two sides extending in the second direction D2.

The main portion 531 overlaps with the mold member facing portion 521 of the insulation layer 52 in the thickness direction of the element-side metal layer 53. Specifically, a portion of the insulation layer 52 that overlaps with the main portion 531 in the thickness direction of the element-side metal layer 53 forms a portion of the mold member facing portion 521. Thus, the mold member facing portion 521 faces the mold member 41 in a portion that is located close to the imaginary line L in the first direction D1, and is covered by the element-side metal layer 53 in a portion other than the portion that is located close to the imaginary line L in the first direction D1.

The element-side metal layer 53 is joined to the power elements 40 at the main portion 531. In detail, the element-side metal layer 53 and the power elements 40 are joined by soldering the heat releasing plate 43 to the main portion 531. In other words, the heat releasing plate 43 is soldered to the element-side metal layer 53. In FIG. 2, a portion of the element-side metal layer 53 where a soldered portion is located is indicated by a chain double-dashed line.

The terminal-side surface 411 is located outside the element-side metal layer 53 so that a portion of the mold member 41 faces the element-side metal layer 53, and the other portion of the mold member 41 and the leads 42 face the insulation layer 52. The mold member facing portion 521 faces the mold member 41 in the thickness direction of the metal base circuit board 50 outside the element-side metal layer 53. In addition, the lead facing portion 522 extends from the mold member facing portion 521 to an outside the element-side metal layer 53 so that the lead facing portion 522 faces at least the first portion 421 in the thickness direction of the metal base circuit board 50.

In other words, in the thickness direction of the metal base circuit board 50, the power elements 40 each have a portion extending along the insulation layer 52 via the main portion 531 and another portion extending along the insulation layer 52 without the main portion 531 being interposed. Specifically, the power elements 40 each are located adjacent to the insulation layer 52 via the main portion 531 in a portion of the mold member 41 close to a surface opposite from the terminal-side surface 411. The power elements 40 each are located adjacent to the mold member facing portion 521 in a portion of the mold member 41 that is located close to the terminal-side surface 411. In addition, the power elements 40 each are located adjacent to the lead facing portion 522 in (each of) the leads 42. That is, the power elements 40 each are disposed on the element-side metal layer 53 so that the terminal-side surface 411 extends beyond the region surrounded by the edge portion 534, when the metal base circuit board 50 is viewed from the thickness direction thereof in the plan view.

The element-side metal layer 53 includes the outer portion 532 that extends outward relative to the mold member 41 in a direction in which the plurality of leads 42 is arranged. More specifically, the element-side metal layer 53 has the outer portion 532 that extends from the boundary B of the main portion 531. The outer portion 532 does not face its associated one of the power elements 40 in the thickness direction of the metal base circuit board 50.

The outer portion 532 of the present embodiment extends from three sides of the boundary B excluding a side of the boundary B that coincides with the edge portion 534. The outer portion 532 surrounds the main portion 531 along the three sides of the boundary B excluding the side of the boundary B that coincides with the edge portion 534. Note that the outer portion 532 and the two protruding portions 533, which will be described later, are separated by an extension line of the side of the boundary B that coincides with the edge portion 534. A portion of the element-side metal layer 53, which is provided by combination of the main portion 531 and the outer portion 532, has a rectangular shape.

Each of the two protruding portions 533 further extends from the outer portion 532 in the direction in which the first portion 421 extends. More specifically, the protruding portions 533 extend in the first direction D1 from a portion of the outer portion 532 close to the leads 42 in the first direction D1. The protruding portions 533 do not face its associated one of the power elements 40 in the thickness direction of the metal base circuit board 50.

As illustrated in FIG. 5, when the metal base circuit board 50 is viewed from the thickness direction thereof in the plan view, the two protruding portions 533 are spaced from the leads 42 in the second direction D2, and extend from the outer portion 532. Specifically, the two protruding portions 533 are spaced from each other in the second direction D2. The leads 42 and the two protruding portions 533 are arranged in order of one of the protruding portions 533, the leads 42, and the other of the protruding portions 533 in the second direction D2. Thus, when the metal base circuit board 50 is viewed from the thickness direction thereof in the plan view, the mold member facing portion 521 and the lead facing portion 522 are adjacent to each other and interposed between the two protruding portions 533 in the insulation layer 52.

The element-side metal layer 53 includes the main portion 531, the outer portion 532, and the protruding portions 533 so that the spaced distances from the first portion 421 to the main portion 531, the outer portion 532, and the protruding portions 533 become greater than or equal to the desired distance. Specifically, the areas and the positions of the main portion 531, the outer portion 532, and the protruding portions 533 of the element-side metal layer 53 are set so that the spaced distance from each of the parts on the first portion 421 as a starting point to the main portion 531, the outer portion 532, and the protruding portion 533 becomes greater than or equal to the desired distance. This provides insulation between the element-side metal layer 53 and the leads 42.

### Temperature Sensor

As illustrated in FIG. 1 and FIG. 2, the temperature sensor 70 is provided on the metal base circuit board 50. The temperature sensor 70 measures the temperature of each of the power elements 40. An example of the temperature sensor 70 is a thermistor. The temperature sensor 70 is provided on the element-side metal layer 53 in the metal base circuit board 50. More specifically, the temperature sensor 70 is provided on one of the protruding portions 533. The temperature sensor 70 is soldered to one of the protruding portions 533.

The temperature sensor 70 is mounted on the metal base circuit board 50. The temperature sensor 70 is electrically connected to the element-side metal layer 53 in the metal base circuit board 50. That is, the temperature sensor 70 is electrically connected to the circuit board 31. More specifically, the temperature sensor 70 is electrically connected to the circuit pattern 32 through the element-side metal layer 53 and the conductive member 54. The temperature sensor 70 is connected to the controller 33 as illustrated in FIG. 1 through the circuit pattern 32. The temperature sensor 70 is configured to send the measured temperature of each of the power elements 40 to the controller 33. When the temperature of the power elements 40 measured by the temperature sensor 70 becomes high, i.e., exceeding a preset allowable value, for example, the controller 33 stops controlling of the electric motor 13 by the inverter 30.

### Operation of Present Embodiment

The operation of the present embodiment will be described.

The electric compressor 10 compresses the refrigerant drawn into the housing 11 using the compression part 12 driven by the electric motor 13. In the electric compressor 10, the inverter 30 converts direct current provided from the outside into alternating current to drive the electric motor 13 with the alternating current. The inverter 30 converts direct current into alternating current by the operation of the power elements 40 mounted on the circuit board 31.

During the operation of the electric compressor 10, each of the power elements 40 generates heat. The generation of heat in each of the power elements 40 is caused by the switching element S, which is accommodated in the mold member 41 and generates heat during this operation. The heat generated in each of the power elements 40 is transmitted to the metal base circuit board 50. That is, the heat generated in each of the power elements 40 is transmitted to the element-side metal layer 53. In the metal base circuit board 50, the heat transmitted from the power elements 40 reaches the metal layer 51 through the insulation layer 52. The metal layer 51 releases the heat generated in the power elements 40 to the inverter housing 20. The inverter housing 20 that receives the heat is cooled by the refrigerant drawn into the housing 11.

The direct current applied to the electric compressor 10 is supplied to the switching element S in the mold member 41 through the leads 42. The insulation layer 52 includes the mold member facing portion 521, and the lead facing portion 522 that extends from the mold member facing portion 521 so as to face the mold member 41 and the first portion 421 respectively in the thickness direction of the metal base circuit board 50. With this configuration, the mold member facing portion 521 and the lead facing portion 522 increase the creepage distance between the leads 42 and the metal layer 51.

### Effects of Present Embodiment

The effects of the present embodiment will be described.
(1) The electric compressor 10 includes the insulation layer 52 providing insulation between the leads 42 and the metal layer 51, and the metal base circuit board 50 through which the heat generated in the power elements 40 is transmitted to the inverter housing 20. For example, in a case where the inverter 30 does not have the metal base circuit board 50, the power elements 40 and the heat sink that is provided on the inverter plate 21 may be insulated by a sheet, which is made of an insulating material and provided separately from the heat sink. As compared with this case, the electric compressor 10 has the metal layer 51 and the metal base circuit board 50 having the insulation layer 52 that is formed integrally with the metal layer 51, so that the size of the electric compressor 10 in the thickness direction of the metal base circuit board 50 may be reduced.

In addition, the insulation layer 52 includes the mold member facing portion 521, and the lead facing portion 522 that extends from the mold member facing portion 521 and faces the first portion 421. The insulation layer 52 including the mold member facing portion 521 and the lead facing portion 522 allows the creepage distance between the leads 42 and the metal layer 51 to be increased. For example, as compared with a case where a creepage distance is increased by increasing the thickness of the insulation layer 52, an increase in size of the electric compressor 10 in the thickness direction of the metal base circuit board 50 may be suppressed. Since the creepage distance is increased by the mold member facing portion 521 and the lead facing portion 522, it is suppressed that the electric compressor 10 decreases the heat releasing performance of the power elements 40, as compared with the case where the creepage distance is secured by increasing the thickness of the insulation layer 52. Accordingly, the electric compressor 10 secures the creepage distance and suppresses the increase in size and the decrease in the heat releasing performance of the power elements 40.
(2) The metal base circuit board 50 includes the insulation layer 52 that is located between the mold member 41 and the metal layer 51. Even when the potential difference between the heat releasing plate 43 and the metal layer 51 occurs, the insulation layer 52 may provide insulation between its associated one of the power elements 40 and the metal layer 51, and the size of the electric compressor 10 may be decreased while securing the creepage distance between the leads 42 and the metal layer 51.
(3) The metal base circuit board 50 includes the element-side metal layer 53. The mold member facing portion 521 and the lead facing portion 522 of the insulation layer 52 are located outside the element-side metal layer 53. With this configuration, in the thickness direction of the metal base circuit board 50, a portion of the mold member 41 faces the element-side metal layer 53, and the other portion of the mold member 41 faces the insulation layer 52 without the element-side metal layer 53 being interposed therebetween. Thus, in the metal base circuit board 50, the heat generated from its associated one of the power elements 40 is transmitted to the element-side metal layer 53 through the mold member 41. Since the insulation layer 52 includes the mold member facing portion 521 and the lead facing portion 522, the creepage distances between the leads 42 and the element-side metal layer 53, and between the leads 42 and the metal layer 51 are increased. With this configuration, each of the power elements 40 may release the heat in the mold member 41 to the element-side metal layer 53 and increase an insulation distance from each of the metal layer 51 and the element-side metal layer 53 to the leads 42. As a result, the electric compressor 10 may release the heat through the element-side metal layer 53 and secure the creepage distance from each of the metal layer 51 and the element-side metal layer 53 to the leads 42.
(4) The power elements 40 are attached to the metal base circuit board 50 by soldering the heat releasing plate 43 to the element-side metal layer 53. In this case, the inverter 30 decreases in size, as compared with a case where each of the power elements 40 is attached to the metal base circuit board 50 with a leaf spring, for example.

Moreover, the heat generated in the power elements 40 is transmitted to the element-side metal layer 53 through the heat releasing plate 43 and the solder. That is, the inverter 30 may improve the heat releasing performance, as compared with a case where each of the power elements 40 is attached to the metal base circuit board 50 by pressing using the leaf spring, for example.
(5) The metal base circuit board 50 is joined to the power elements 40 through the element-side metal layer 53 that is formed on the insulation layer 52. Since the metal base circuit board 50 has the element-side metal layer 53, breakage of the insulation layer 52 by a conductive foreign object produced by a soldering operation, for example, may be avoided.
(6) The element-side metal layer 53 includes the outer portion 532 that extends outward relative to the mold member 41. The element-side metal layer 53 includes the outer portion 532, which increases a heat capacity That is, the electric compressor 10 has the outer portion 532 on the element-side metal layer 53, so that a cooling performance of the power elements 40 may be improved.
(7) The heat generated in each of the power elements 40 is transmitted to the main portion 531 that is a portion of the element-side metal layer 53, and then, to the outer portion 532. Even in a case where the sharp temperature rise occurs in each of the power elements 40, for example, when the electric compressor 10 is started, the element-side metal layer 53 may keep the heat by the outer portion 532 and release the heat to the metal layer 51 through the insulation layer 52. Thus, even in a case where the sharp temperature rise occurs in each of the power elements 40, the element-side metal layer 53 suppresses heat accumulation by preventing the amount of heat absorbed from exceeding the amount of the heat released. As described above, the metal base circuit board 50 has the outer portion 532 in the element-side metal layer 53, so that the cooling performance of the power elements 40 may be improved.
(8) The element-side metal layer 53 includes the protruding portions 533 that extend from the outer portion 532. With this configuration, the element-side metal layer 53 may increase the heat capacity, as compared with a case where the protruding portions 533 are not provided in the element-side metal layer 53. That is, the electric compressor 10 may improve the cooling performance of the power elements 40, as compared with a case where the outer portion 532 is not provided in the element-side metal layer 53.
(9) The element-side metal layer 53 includes the protruding portions 533 spaced from the leads 42 when the metal base circuit board 50 is viewed from the thickness direction thereof in the plan view. That is, the metal base circuit board 50 increases the area of element-side metal layer 53 while securing the insulation from the leads 42. As a result, the element-side metal layer 53 may improve the cooling performance of the power elements 40 while securing the insulation from the leads 42.
(10) The inverter 30 has the temperature sensor 70 that is provided on the metal base circuit board 50. The temperature of each of the power elements 40 is measured by the temperature sensor 70 provided on the metal base circuit board 50. For example, as compared with a case where the temperature sensor 70 is mounted on the circuit board 31, the temperature sensor 70 may measure temperatures of each of the power elements 40 at positions close to the power elements 40. As a result, the temperature sensor 70 may measure the temperatures of the power elements 40 precisely, as compared with a case where the temperature sensor 70 is mounted on the circuit board 31, for example.

### Modification

The above-described embodiment may be modified as follows. The above-described embodiment and the following modifications may be combined with each other as long as they do not technically contradict each other.

The temperature sensor 70 may be mounted on the circuit board 31 to measure the temperature of each of the power elements 40. In this case, the inverter 30 does not have to include the conductive member 54.

The element-side metal layer 53 does not have to include the protruding portions 533. For example, the element-side metal layer 53 may have a rectangular shape formed of the main portion 531 and the outer portion 532.

The shape of the outer portion 532 is not limited to that in the above-described embodiment. The outer portion 532 may extend from one of the edges of the main portion 531. In short, the outer portion 532 only needs to extend outward relative to the mold member 41.

The element-side metal layer 53 does not have to include the outer portion 532. For example, the element-side metal layer 53 may only be formed of the main portion 531.

The heat releasing plate 43 does not have to be soldered to the element-side metal layer 53. For example, the power elements 40 may be pressed by the leaf spring provided on the metal base circuit board 50 with the heat releasing plate 43 in contact with the element-side metal layer 53.

The metal base circuit board 50 and the element-side metal layer 53 may be separately provided. That is, the metal base circuit board 50 may use a metal member that has a plate shape and is provided on the insulation layer 52 as the element-side metal layer 53.

The metal base circuit board 50 does not have to include the element-side metal layer 53. In this case, each of the power elements 40 is attached to the metal base circuit board 50 with the mold member 41 facing the insulation layer 52.

The mold member 41 does not have to include the heat releasing plate 43. In this case, the insulation layer 52 is interposed between each of the mold member 41 and the leads 42 and the metal layer 51.

The power elements 40 are not limited to the discrete-type IGBT, but may be a metal oxide semiconductor field effect transistor (MOSFET). For example, a power module in which the power elements 40 are modularized or an IGBT in which a plurality of the switching elements S is modularized may be used. Also, in each of the power elements 40, the leads 42 may extend from the inside to the outside of the mold member 41 through a plurality of the side surfaces of the mold member 41. In this case, the power elements 40 include the terminal-side surfaces 411, corresponding to the number of the side surfaces through which the leads 42 extend.

The power elements 40 each may be an intelligent power module (IPM) including a plurality of the switching elements S. In short, the power elements 40 each only need to be configured to convert the direct current into the alternating current, by mounting one or more of the power elements 40 on the circuit board 31. Specific configuration of each of the power elements 40, such as a shape and the number of the leads 42 or the number of the switching elements S, for example, may change as appropriate depending on the type of the power elements 40 used in the inverter 30.

When the metal base circuit board 50 has an insulated IPM that is provided on the mold member 41 as the power elements 40, a region where the insulation layer 52 is not interposed between the mold member 41 and the metal layer 51 may be provided. In other words, the insulation layer 52 does not have to have the mold member facing portion 521 over the entire portion that overlaps with the mold member 41 in the thickness direction of the metal base circuit board 50. In this case, the insulation layer 52 may have the mold member facing portion 521 extending between the mold member 41 and the metal layer 51 to the extent that the required creepage distance between the leads 42 and the metal layer 51 is secured.

In this case, the heat generated in each of the power elements 40 is transmitted to the metal layer 51 without using the insulation layer 52. As a result, the metal base circuit board 50 may improve the cooling performance of the power elements 40.

The voltage of the power source E is not limited to 800 V. Depending on the voltage of the power source E, the insulation distance between the leads 42 and the metal layer 51 may change as appropriate.

A mounting target of the electric compressor 10 is not limited to a vehicle, but may be optional.

The electric compressor 10 does not have to be used in the vehicle air conditioner 100. The electric compressor 10 may be used in other device. For example, when a vehicle is a fuel cell vehicle on which a fuel cell is mounted, the electric compressor 10 may be used as a supply device that supplies air to the fuel cell. In this case, fluid compressed by the compression part 12 is air.

What is claimed is

1. An electric compressor comprising:
a compression part configured to compress fluid;
an electric motor configured to drive the compression part;
an inverter configured to drive the electric motor; and
an inverter housing accommodating the inverter,
the inverter having:
a circuit board on which a circuit pattern is provided, the circuit pattern forming a circuit of the inverter; and
a power element including a mold member in which a switching element forming the circuit of the inverter is molded in resin, and a plurality of leads that is electrically connected to the switching element in the mold member, extends through a side surface of the mold member, and is electrically connected to the circuit pattern,
the plurality of leads each having a first portion that extends toward an outside of the mold member from the side surface of the mold member, and a second portion that is bent from the first portion and extends toward the circuit board, wherein
the inverter further includes a metal base circuit board disposed between the power element and the inverter housing,
the metal base circuit board includes a metal layer that releases heat generated in the power element to the inverter housing, and an insulation layer that is integrally formed with the metal layer on a surface of the metal layer,
the power element and the metal base circuit board are accommodated in the inverter housing so that the first portion, the insulation layer, and the metal layer are arranged in this order in a thickness direction of the metal base circuit board, and
the insulation layer has a mold member facing portion extending in the thickness direction of the metal base circuit board so that the mold member facing portion faces the mold member and a lead facing portion that extends from the mold member facing portion so that the lead facing portion faces at least the first portion in the thickness direction of the metal base circuit board.

2. The electric compressor according to claim 1, wherein
the mold member includes a heat releasing plate that releases heat of the switching element, and
the mold member facing portion is interposed between the heat releasing plate and the metal layer.

3. The electric compressor according to claim 1, wherein
the metal base circuit board has an element-side metal layer on a side opposite from the metal layer with the insulation layer interposed between the element-side metal layer and the metal layer,
the power element and the metal base circuit board are accommodated in the inverter housing so that the mold member, the element-side metal layer, the insulation layer, and the metal layer are arranged in this order in the thickness direction of the metal base circuit board,
the mold member facing portion faces the mold member in the thickness direction of the metal base circuit board outside the element-side metal layer, and
the lead facing portion extends from the mold member facing portion to an outside of the element-side metal layer so that the lead facing portion faces at least the first portion in the thickness direction of the metal base circuit board.

4. The electric compressor according to claim 3, wherein
the mold member includes a heat releasing plate that releases heat of the switching element, and
the heat releasing plate is soldered to the element-side metal layer.

5. The electric compressor according to claim 3, wherein
the element-side metal layer includes an outer portion that extends outward relative to the mold member in a direction in which the plurality of leads is arranged.

6. The electric compressor according to claim 5, wherein
the element-side metal layer includes a protruding portion that extends further from the outer portion in a direction in which the first portion extends so that the protruding portion is located adjacent to the mold member facing portion and the lead facing portion in the direction in which the plurality of leads is arranged.

7. The electric compressor according to claim 1, wherein
the metal base circuit board has a temperature sensor that measures a temperature of the power element and is electrically connected to the circuit board.
